(19) United States
(12) Patent Application Publication
(10) Pub. No.: US 2024/0395661 A1
(43) Pub. Date: Nov. 28, 2024

(54) IN-SITU MICRO-FLUIDIC CHANNELS FOR HEAT DISSIPATION IN GLASS SUBSTRATE

(71) Applicant: Intel Corporation, Santa Clara, CA (US)

(72) Inventors: Numair Ahmed, Chandler, AZ (US); Suddhasattwa Nad, Chandler, AZ (US); Mohammad Mamunur Rahman, Gilbert, AZ (US); Brandon C. Marin, Gilbert, AZ (US); Sashi S. Kandanur, Phoenix, AZ (US); Srinivas Venkata Ramanuja Pietambaram, Chandler, AZ (US); Darko Grujicic, Chandler, AZ (US); Gang Duan, Chandler, AZ (US); Banjamin Duong, Phoenix, AZ (US)

(21) Appl. No.: 18/202,046

(22) Filed: May 25, 2023

(51) Int. Cl. H01L 23/473; H01L 23/31; H01L 23/373; H01L 23/48; H01L 23/498

(52) U.S. Cl. CPC H01L 23/473; H01L 23/3128; H01L 23/3731; H01L 23/481; H01L 23/49822; H01L 23/5389

(57) ABSTRACT

An electronic device and associated methods are disclosed. In one example, the electronic device includes a glass core layer having a first surface layer and a second surface layer; multiple channels within the glass core layer between the first surface and the second surface layer; and a first redistribution layer (RDL) including multiple sublayers of conductive traces formed in an organic material, wherein a first surface of the RDL contacts the first surface of the glass core layer.

### TECHNICAL FIELD

Embodiments pertain to packaging of integrated circuits (ICs). Some embodiments relate to a package substrate having a glass core.

### BACKGROUND

Electronic systems often include integrated circuits (ICs) that are interconnected and packaged as a subassembly. It is desired to integrate multiple types of IC dies into a single package to create an efficient system in a package. However, as packaged electronic systems become larger due to adding more IC dies, the area form factor (e.g., X-Y dimensions) of the packages becomes larger. If the area form factor of a package becomes too large, the package can be susceptible to warping. One approach to reduce warping is to replace the organic core material of the package substrate with a glass core. But integrating system functionality into a package substrate with a glass core can increase the generated heat that needs to be removed for safe and efficient operation. It is desired to have electronic system packages that address these thermal concerns, and other technical challenges.

### BRIEF DESCRIPTION OF THE DRAWINGS

FIG. 1 is an illustration of an example of portions of an electronic device having a substrate that includes a stiffening glass core layer, in accordance with some embodiments.

FIG. 2 is an example of a cooling system to provide liquid coolant to the electronic device of FIG. 1, in accordance with some embodiments.

FIG. 3 illustrates another cross section view of the example of the electronic device in FIG. 1, in accordance with some embodiments.

FIG. 4 shows a flow diagram of an example of a method of manufacture of an electronic package substrate, in accordance with some example embodiments.

FIGS. 5A-5F illustrate portions of a process flow of the method of FIG. 4, in accordance with some example embodiments.

FIG. 6 shows a system that may incorporate channels formed in a substrate to carry fluid to cool the system, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

To meet the demand for increased functional complexity in electronic devices, manufacturers integrate multiple types of integrated circuits (ICs) dies in a single electronic package to create an efficient electronic system in a package. The trend to package multiple IC dies into one electronic system can lead to needing large package sizes to fit all the dies. The current package technologies for electronic packaging are limited in the area form factor (e.g., X-Y dimension) that can be achieved due to warping.

The susceptibility to warping limits the number of IC dies that can be included in multi-dies assemblies and limits the size of an electronic package. Package warpage is the deviation from flatness caused by internal stress of the electronic package. Warpage can lead to different solder joint geometries between the center and the edge of the interconnected area, which can reduce the reliability. In addition, warpage can lead to solder balls bridging and interconnect opens or shorts between the solder balls which reduces the assembly yield.

Integrating increased functionality in a package substrate leads to new approaches for package architectures. One approach is to replace the organic core material of the package substrate with a glass core. The glass of the glass core may include a silicate-based glass (e.g., lithium-silicate, borosilicate, aluminum silicate, etc.). In variations, the glass panel includes a lower quality glass (e.g., glass made with soda lime), or a higher quality glass (e.g., quartz glass made with fused silica). In some examples, the glass core includes at least 70% silica.

As more functionality is integrated into electronic devices, power consumption of the devices increases. The increased power draw increases heat that needs to be moved away from the electronics package. Using glass in the substrate core as a stiffening material to reduce warpage can create challenges in managing the heat due to its reduced thermal conductivity of glass in comparison to organic cores. Using a glass core also presents an opportunity for unique architectures that enable the removal of heat using the core itself.

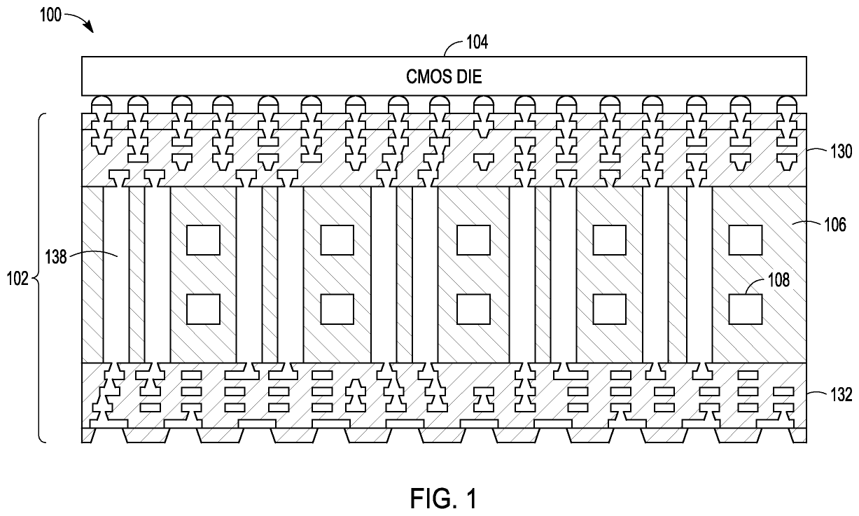

FIG. 1 illustrates a cross section view of an example of portions an electronic device 100 that includes an electronic package substrate 102 and an integrated circuit (IC) die 104 mounted on the top surface of the substrate 102. The IC die 104 can be a complex component that generates significant heat such as a CPU die for example. The substrate 102 includes a glass core layer 106 that serves as a stiffening material for the substrate 102. To improve the thermal performance of the electronic device, the glass core layer 106 includes channels 108 within the glass core layer 106. The channels 108 can be covered trenches that are sized to carry an electrically non-conductive liquid to carry heat away from the IC die 104 and other heat generating components of the electronic device 100. In some examples, the glass core layer 106 has a thickness within the range of 150-2000 micrometers (μm). The dimensions of the channels 108 may include one or both of a width and depth in the range of 50-100 μm.

The electronic substrate 102 includes a top redistribution layer 130 (RDL) and a bottom RDL 132. The RDLs include multiple sublayers of conductive traces formed in an organic material. The thickness of the RDLs is exaggerated in the Figure for simplicity of the drawing. In an actual implementation, the RDLs are thin enough that the channels 108 of the core layer carry the liquid coolant close enough to the IC die 104 to absorb heat from the IC die 104. In the example of FIG. 1, there are two rows of channels 108: a top row and a bottom row. The top row is nearer to the top RDL, and the bottom row is nearer to the bottom RDL. The top row of channels may remove heat away from the IC die 104 and the bottom row of channels may remove heat away from electronic components contacting the bottom RDL 132. The channels of the core layer may have different sizes. For example, the channels of the top row may be larger than the channels of the bottom row if more heat is needed to be absorbed by the channels of the top row.

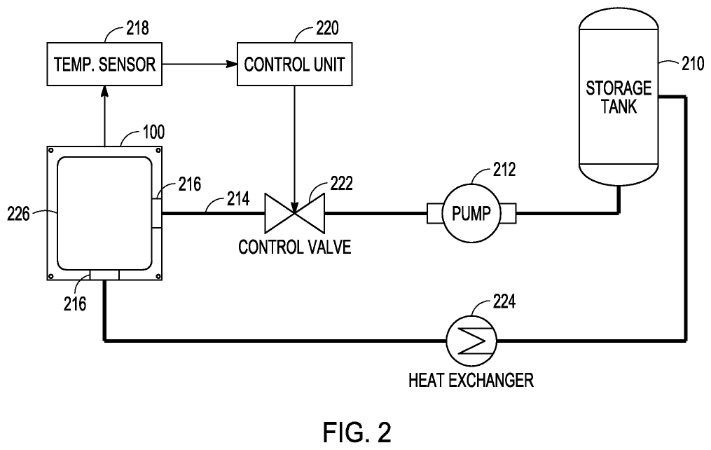

FIG. 2 is an example of a cooling system 200 to provide liquid coolant to the electronic device 100 of FIG. 1 and control cooling the electronic device 100. Electrically non-conductive liquid coolant is provided to the electronic device 100 from storage tank 210 using a pump 212. Ducts 214 or channels route the coolant to the electronic device 100. Manifolds 216 transfer the coolant between the ducts 214 and the channels 108 of the core layer of the electronic device 100.

A temperature sensor 218 monitors the temperature of the electronic device 100. A control unit 220 includes electronic circuits to control opening and closing of a control valve 222 based on the sensed temperature of the electronic device 100. When the temperature reaches or exceeds a threshold temperature, the control unit 220 opens the control valve 222 to circulate the coolant to transfer heat away from the electronic device 100. Heat exchanger 224 cools the heated coolant pulled away from the electronic device. A heat spreader 226 may be attached to the IC die of the electronic device 100 that can contact a heat sink to further dissipate heat into air above the electronic device. The control unit 220 may close the control valve 222 when the sensed temperature of the electronic device 100 drops below a specified temperature lower than the threshold temperature.

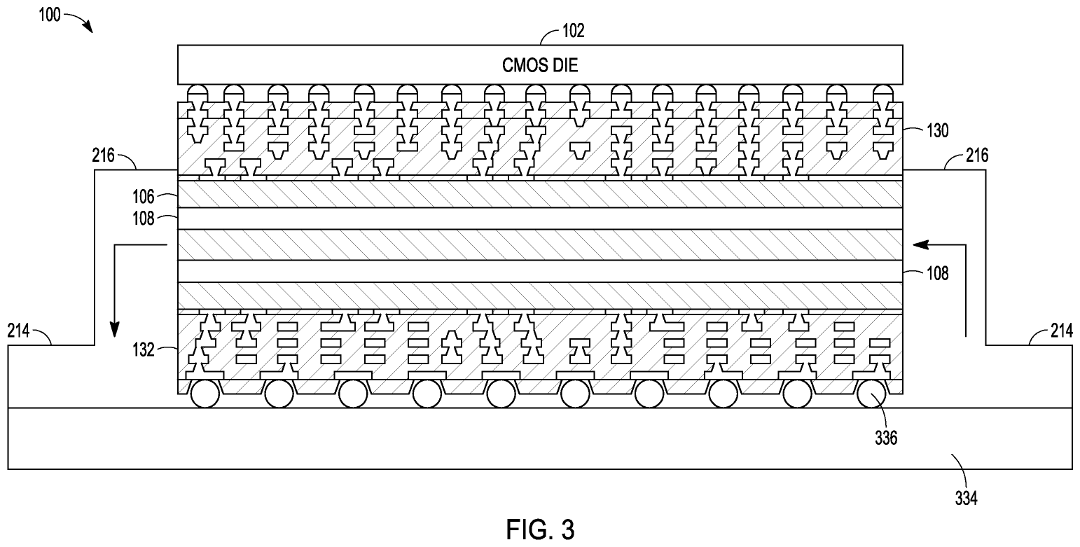

FIG. 3 illustrates another cross section view of the example of the portions the electronic device 100 in FIG. 1. FIG. 3 shows the channels 108 running the length of the glass core layer 106. FIG. 3 also shows the manifolds 216 that transfer the liquid coolant between the channels 108 of the glass core layer 106 and the duct 214 to carry the coolant to and from the electronic device 100. The bottom RDL 132 of the electronic package substrate is attached to a printed circuit board 334 (PCB). The PCB 334 may be a motherboard. The bottom RDL 132 includes bonding pads and the bottom RDL is attached to the PCB 334 using solder bumps 336 (e.g., ball grid array solder bumps). The ducts 214 can be arranged on the surface of the PCB 334. In some examples, the electronic package substrate is attached to the PCB 334 using a PCB socket and the manifolds are included in the PCB socket.

Returning to FIG. 1, the glass core layer 106 includes through glass vias (TGVs) 138. The TGVs 138 include a conductive material (e.g., metal) to provided electrical continuity between the conductive traces of the top RDL 130 and the conductive traces of the bottom RDL 132. The TGVs 138 can be placed adjacent to a set of channels or between channels. The top RDL 130 can provide electrical continuity between one or more of the TGVs 138 and IC die 104. The bottom RDL 132 can provide electrical continuity between one or more of the TGVs and the PCB 334 of FIG. 3. Thus, the RDLs and TGVs can provide electrical continuity between the IC die 104 and the PCB 334.

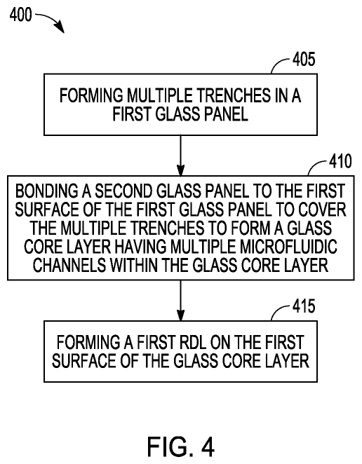

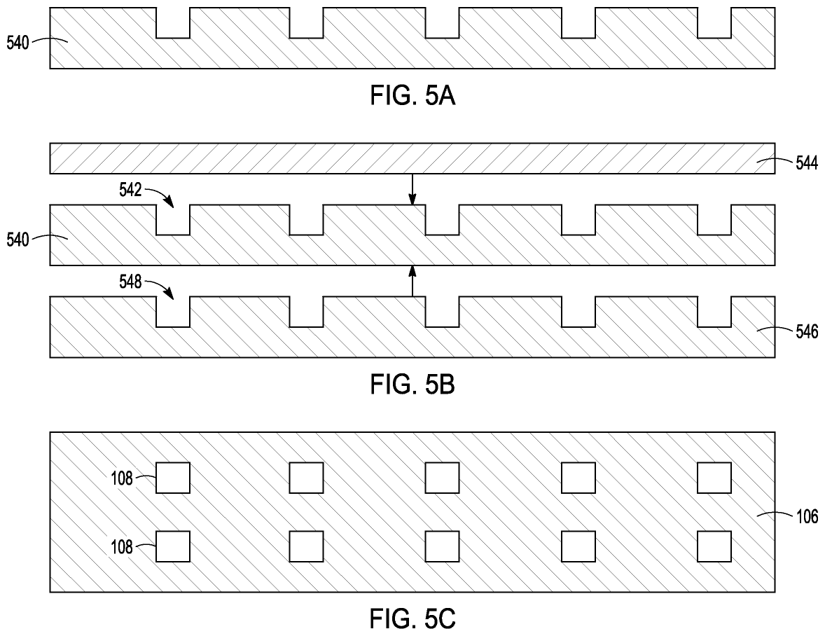

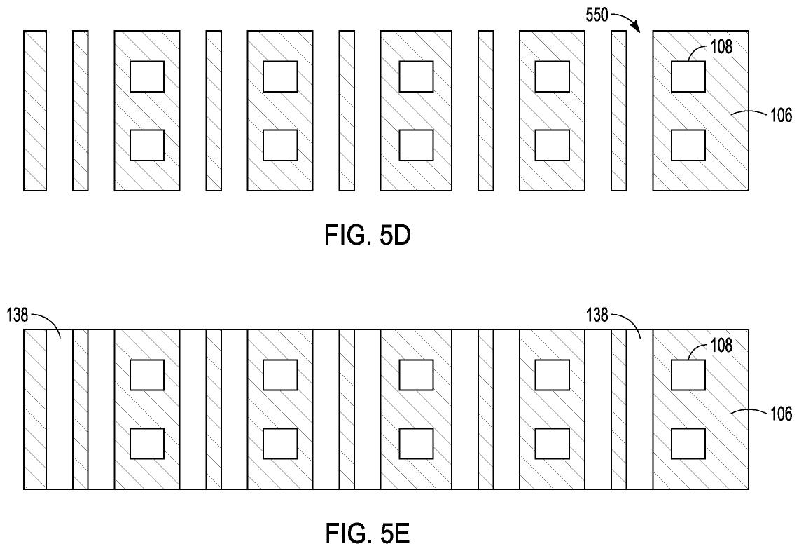

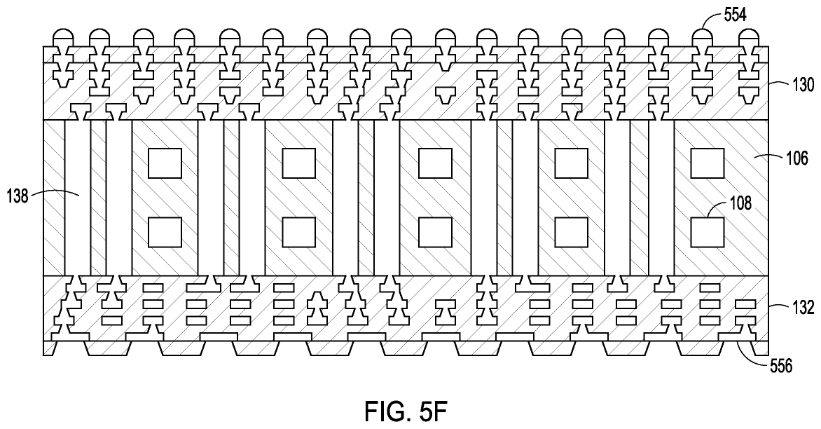

FIG. 4 is a flow diagram of an example of a method 400 of forming an electronic package substrate (e.g., the electronic substrate 102 of FIG. 1). FIGS. 5A-5F illustrate portions of a process flow of the method of FIG. 4.

In FIG. 4 at block 405, multiple trenches are formed in a first glass sub-layer. FIG. 5A illustrates a cross section of a glass sub-layer 540. The glass sub-layer may be formed from a glass panel. The glass panel can include the types of glass described previously herein. Trenches 542 are formed in the top surface of the glass sub-layer 540 that run the length of the glass sub-layer 540. The trenches 542 can be formed by etching or laser drilling.

At block 410 of FIG. 4, a second glass sub-layer is bonded to a first surface of the first glass sub-layer to cover the multiple trenches. FIG. 5B shows a second glass sub-layer 544 being bonded to the top surface of the first glass sub-layer 540. The glass sub-layers can be bonded using heat and pressure, or by using an adhesive. The two glass sub-layers are bonded to form a monolithic glass core layer. The second glass sub-layer 544 covers the trenches to form a row of channels 108 in the monolithic glass core layer.

In FIG. 5B, trenches 548 are formed in the top surface of a third glass sub-layer 546. The third glass sub-layer 546 is bonded to the bottom surface of the first glass sub-layer 540 to form a second row of channels. FIG. 5C shows the resulting monolithic glass core layer 106 having two rows of channels 108. The trenches 542 of the first glass sub-layer 540 can be formed to have a different size than the trenches of the third glass sub-layer 546 (e.g., a larger width and/or depth), resulting in the first row of channels 108 having a different size than the second row of channels 108. The cross sections of the channels are shown to be squares, but the cross sections may have a rectangular shape. In certain examples, the cross section of one row of channels 108 (e.g., the top row) can be square while the bottom row of channels 108 can be rectangular. The cross section can have other shapes. For instance, the cross section can be a semicircle having a bottom curved surface.

In FIG. 5C, openings 550 are formed in the glass core layer 106. The openings 550 will be used to form through glass vias (TGVs) in the glass core layer 106. The openings 550 can be formed by etching or laser drilling. The bonding of the multiple glass sub-layers into a monolithic glass core layer enables the etching or drilling of the openings.

In FIG. 5D the openings are filled with a conductive material such as metal to form TGVs 138. The TGVs 138 extend through the glass sub-layers to the top and bottom surfaces of the glass core layer 106. The TGVs 138 can be adjacent to a channel 108, and the TGVs can be in between channels 108.

Returning to FIG. 4 at block 415, a first top RDL 130 is formed on the top surface of the glass core layer 106. FIG. 5E shows the top RDL 130. The top RDL 130 includes conductive traces (e.g., metal traces) built up in multiple sublayers in an organic material (e.g., FR4). The top RDL 130 includes bonding pads and solder bumps 554 attached to the bonding pads. One or more IC dies (e.g., IC die 104 in FIG. 1) can be attached to the solder bumps 554 and bonding pads. The top RDL 130 can provide electrical continuity between the IC dies and the TGVs 138.

FIG. 5E also shows a second bottom RDL 132 formed on the bottom surface of the glass core layer 106 to form an electronic package substrate (e.g., electronic package substrate 102 in FIG. 1). The bottom RDL includes bonding pads 556. Solder bumps (e.g., solder bumps 336 in FIG. 3) can be attached to the bonding pads 556, and the electronic package substrate can be attached to a PCB (e.g., PCB 334 in FIG. 3) using the solder bumps. In some examples, the bonding pads 556 of the bottom RDL 132 are attached to electronic components (e.g., components to provide power to the electronic package substrate).

The TGVs 138 contact the conductive traces of the RDLs. The top RDL 130, the TGVs 138, and the bottom RDL 132 can provide electrical continuity between the IC dies and the PCB. The top row of channels 108 is closer to the top RDL and fluid flowing in the channels can be used to remove heat from the IC dies attached to the top RDL 130. The bottom row of channels 108 is closer to the electronic components attached to the bottom RDL and the bottom row of channels can be used to remove heat from the electronic components attached to the bottom RDL 132.

The methods, devices, and systems described herein provide improved thermal management in electronic device that have a substrate that includes a glass core. Heat from the electronic packaging is removed by electrically non-conductive fluid flowing in channels formed in the glass core. The channels can provide a path for heat extraction that can be used alone or in addition to traditional heat spreaders and heat sinks. An example of an electronic system using assemblies with electronic packaging as described in the present disclosure is included to show an example of a higher level device application

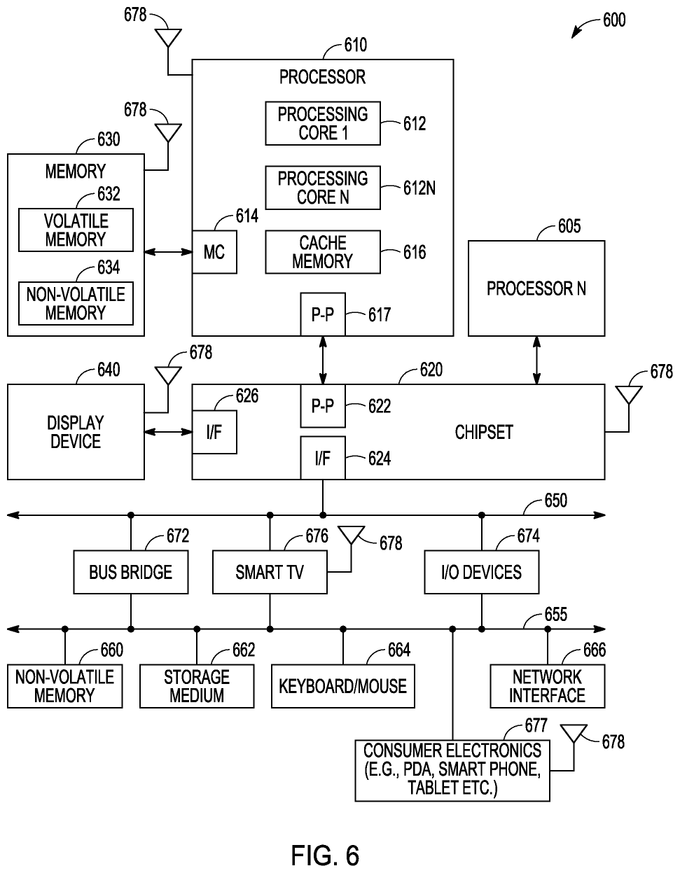

FIG. 6 illustrates a system level diagram, depicting an example of an electronic device (e.g., system) that may include a glass core layer substrate having the channels described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processing cores 612 and 612N, where N is a positive integer and 612N represents the Nth processor core inside processor 610. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices 672, 676, 674, 660, 662, 664, 666, 677, etc. Buses 650 and 655 may be interconnected together via a bus bridge 672. Chipset 620 connects to one or more buses 650 and 655 that interconnect various elements 674, 660, 662, 664, and 666. Chipset 620 may also be coupled to a wireless antenna 678 to communicate with any device configured to transmit and/or receive wireless signals. Chipset 620 connects to display device 640 via interface (I/F) 626. Display 640 may be, for example, a touchscreen, a liquid crystal display (LCD), a plasma display, cathode ray tube (CRT) display, or any other form of visual display device. In some embodiments, processor 610 and chipset 620 are merged into a single SOC. In one embodiment, chipset 620 couples with (e.g., via interface 624) a non-volatile memory 660, a mass storage medium 662, a keyboard/mouse 664, and a network interface 666 via I/F 624 and/or I/F 626, I/O devices 674, smart TV 676, consumer electronics 677 (e.g., PDA, Smart Phone, Tablet, etc.).

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

The methods, devices, and systems described herein provide improved thermal management in electronic systems such as the example system in FIG. 6. To better illustrate the method and apparatuses disclosed herein, a non-limiting list of embodiments is provided here:

Example 1 includes subject matter (such as an electronic device) comprising an electronic package substrate. The electronic package substrate includes a glass core layer having a first surface and a second surface; multiple channels within the glass core layer between the first surface and the second surface; and a first redistribution layer (RDL). The RDL includes multiple sub-layers of conductive traces formed in an organic material, and a first surface of the RDL contacts the first surface of the glass core layer.

In Example 2, the subject matter of Example 1 optionally includes a glass core layer that includes multiple glass sub-layers bonded together.

In Example 3, the subject matter of one or both of Examples 1 and 2 optionally include a glass core layer that includes multiple rows of channels in the glass core layer.

In Example 4, the subject matter of Example 3 optionally includes a first row of channels having a first width, and a second row of channels having a second width different from the first width.

In Example 5, the subject matter of one or both of Examples 3 and 4 optionally includes a second RDL contacting the second surface of the glass core layer. The multiple rows of channels include a first row of channels arranged closer to the first RDL than the second RDL and a second row of channels arranged closer to the second RDL than the first RDL.

In Example 6, the subject matter of one or any combination of Examples 1-5 optionally includes a glass core layer that includes at least one through glass via (TGV) arranged between two channels of the multiple channels.

In Example 7, the subject matter of Example 6 optionally includes a second RDL including multiple sublayers of conductive traces formed in an organic material. A first surface of the second RDL contacts the second surface of the glass core layer, and the at least one TGV provides electrical continuity between a conductive trace of the first RDL and a conductive trace of the second RDL.

In Example 8, the subject matter of one or any combination of Examples 1-7 optionally includes a cross section of a channel of the multiple channels having one of a square shape or a rectangular shape.

In Example 9, the subject matter of one or any combination of Examples 1-7 optionally includes at least one surface of a channel of the multiple channels being a curved surface.

Example 10 includes subject matter (such as an electronic system) comprising an electronic package substrate including a glass core layer including multiple microfluidic channels within the glass core layer between a first surface of the glass core layer and a second surface of the glass core layer; at least one integrated circuit (IC) mounted on the electronic package substrate; and a manifold coupled to the electronic package substrate and configured to provide fluid to the microfluidic channels.

In Example 11, the subject matter of Example 10 optionally includes an electronic package substrate that includes a first redistribution layer (RDL) arranged between the first surface of the glass core layer and the IC, and a through glass via (TGV). The first RDL includes multiple sublayers of conductive traces formed in an organic material. The TGV is arranged in the glass core layer adjacent to a first microfluidic channel of the multiple microfluidic channels. The first RDL provides electrical continuity between the TGV and the IC.

In Example 12, the subject matter of Example 10 optionally includes a first redistribution layer (RDL) arranged between the first surface of the glass core layer and the IC, and a second RDL arranged on the second surface of the glass core layer. The first and second RDL include multiple sublayers of conductive traces formed in an organic material. The glass core layer includes multiple rows of microfluidic channels, including a first row of microfluidic channels closer to the first RDL than the second RDL and a second row of microfluidic channels closer to the second RDL than the first RDL.

In Example 13, the subject matter of Example 12 optionally includes the first row of microfluidic channels having a first width, and the second row of microfluidic channels having a second width different from the first width.

In Example 14, the subject matter of one or both of Examples 12 and 13 optionally includes a printed circuit board (PCB). The electronic package substrate includes a through glass via (TGV) arranged in the glass core layer adjacent to a first microfluidic channel of the multiple microfluidic channels, and the second RDL provides electrical continuity between the TGV and the PCB.

Example 15 includes subject matter (such as a method of forming an electronic package substrate) or can optionally be combined with one or any combination of Examples 1-14 to include such subject matter, comprising forming multiple trenches in a first substrate sub-layer, wherein the multiple trenches are formed in a first surface of the substrate sub-layer; bonding a second substrate sub-layer to the first surface of the first substrate sub-layer to cover the multiple trenches to form a substrate core layer having multiple channels within the substrate core layer; and forming a first redistribution layer (RDL) on a first surface of the glass core layer, wherein the first RDL includes an organic material and multiple sublayers of conductive traces formed in the organic material.

In Example 16, the subject matter of Example 15 optionally includes the first and second substrate sub-layers are first and second glass sub-layers, and the substrate core layer is a glass core layer. The method further includes forming multiple trenches in a first surface of a third glass sub-layer and bonding the first surface of the third glass sub-layer to a second surface of the first glass sub-layer to form a monolithic glass core layer including a second layer of multiple channels in the glass core layer.

In Example 17, the subject matter of Example 16 optionally includes forming the multiple trenches of the third glass sub-layer to have at least one of a different width or depth than the multiple trenches of the third glass sub-layer, and the channels of the second layer of multiple channels have at least one of a different width or depth than the channels of the first layer of multiple channels.

In Example 18, the subject matter of one or both of Examples 16 and 17 optionally includes forming a second RDL on a second surface of the glass core layer. The second RDL includes multiple sublayers of conductive traces formed in an organic material, and wherein the first layer of multiple channels is closer to the first RDL than the second RDL, and the second layer of multiple channels is closer to the second RDL than the first RDL.

In Example 19, the subject matter of Example 18 optionally includes attaching at least one integrated circuit (IC) die on the first RDL and attaching the second RDL to a printed circuit board.

In Example 20, the subject matter of one or any combination of Examples 15-19 optionally includes the first and second substrate sub-layers are first and second glass sub-layers, and the substrate core layer is a glass core layer. The method further includes forming at least one through glass via (TGV) in the glass core layer that extends through the first and second glass sub-layers, and the at least one TGV contacts at least one conductive trace of the first RDL.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device, comprising:
an electronic package substrate including:
a glass core layer having a first surface and a second surface;
multiple channels within the glass core layer between the first surface and the second surface; and
a first redistribution layer (RDL) including multiple sub-layers of conductive traces formed in an organic material, wherein a first surface of the RDL contacts the first surface of the glass core layer.

2. The electronic device of claim 1, wherein the glass core layer includes multiple glass sub-layers bonded together.

3. The electronic device of claim 1, wherein the glass core layer includes multiple rows of channels in the glass core layer.

4. The electronic device of claim 3, wherein the multiple rows of channels include a first row of channels having a first width, and a second row of channels having a second width different from the first width.

5. The electronic device of claim 3, including:
a second RDL contacting the second surface of the glass core layer; and
wherein the multiple rows of channels include a first row of channels arranged closer to the first RDL than the second RDL and a second row of channels arranged closer to the second RDL than the first RDL.

6. The electronic device of claim 1, wherein the glass core layer includes at least one through glass via (TGV) arranged between two channels of the multiple channels.

7. The electronic device of claim 6, including:
a second RDL including multiple sublayers of conductive traces formed in an organic material, wherein a first surface of the second RDL contacts the second surface of the glass core layer; and
wherein the at least one TGV provides electrical continuity between a conductive trace of the first RDL and a conductive trace of the second RDL.

8. The electronic device of claim 1, wherein a cross section of a channel of the multiple channels has one of a square shape or a rectangular shape.

9. The electronic device of claim 1, wherein at least one surface of a channel of the multiple channels is a curved surface.

10. An electronic system, comprising:
an electronic package substrate including:
a substrate core layer including multiple channels within the substrate core layer between a first surface of the substrate core layer and a second surface of the substrate core layer;
at least one integrated circuit (IC) mounted on the electronic package substrate; and
a manifold coupled to the electronic package substrate and configured to provide fluid to the channels.

11. The electronic system of claim 10, wherein the substrate core layer is a glass core layer, and the electronic package substrate includes:
a first redistribution layer (RDL) arranged between the first surface of the glass core layer and the IC, wherein an RDL includes multiple sub-layers of conductive traces formed in an organic material; and
a through glass via (TGV) arranged in the glass core layer adjacent to a first channel of the multiple channels, wherein the first RDL provides electrical continuity between the TGV and the IC.

12. The electronic system of claim 10, wherein the electronic package substrate includes:
a first redistribution layer (RDL) arranged between the first surface of the substrate core layer and the IC, wherein an RDL includes multiple sublayers of conductive traces formed in an organic material;
a second RDL arranged on the second surface of the substrate core layer; and
wherein the glass core layer includes multiple rows of channels, including a first row of channels closer to the first RDL than the second RDL and a second row of channels closer to the second RDL than the first RDL.

13. The electronic system of claim 12, wherein the first row of channels has a first width, and the second row of channels has a second width different from the first width.

14. The electronic system of claim 12, including:
a printed circuit board (PCB); and
wherein the electronic package substrate includes:
a through via arranged in the substrate core layer adjacent to a first channel of the multiple channels, and wherein the second RDL provides electrical continuity between the through via and the PCB.

15. A method of forming an electronic package substrate, the method comprising:
forming multiple trenches in a first substrate sub-layer, wherein the multiple trenches are formed in a first surface of the first substrate sub-layer;
bonding a second substrate sub-layer to the first surface of the first substrate sub-layer to cover the multiple trenches to form a substrate core layer having multiple channels within the substrate core layer; and
forming a first redistribution layer (RDL) on a first surface of the substrate core layer, wherein the first RDL includes an organic material and multiple sublayers of conductive traces formed in the organic material.

16. The method of claim 15, including:
wherein the first and second substrate sub-layers are first and second glass sub-layers, and the substrate core layer is a glass core layer; and
wherein the method further includes:
forming multiple trenches in a first surface of a third glass sub-layer; and
bonding the first surface of the third glass sub-layer to a second surface of the first glass sub-layer to form a monolithic glass core layer including a second layer of multiple channels in the glass core layer.

17. The method of claim 16, including forming the multiple trenches of the third glass sub-layer to have at least one of a different width or depth than the multiple trenches of the third glass sub-layer, and the channels of the second layer of multiple channels have at least one of a different width or depth than the channels of the first layer of multiple channels.

18. The method of claim 16, including:
forming a second RDL on a second surface of the glass core layer, wherein the second RDL includes multiple sublayers of conductive traces formed in an organic material, and wherein the first layer of multiple channels is closer to the first RDL than the second RDL, and the second layer of multiple channels is closer to the second RDL than the first RDL.

19. The method of claim 18, including:
attaching at least one integrated circuit (IC) die on the first RDL; and
attaching the second RDL to a printed circuit board.

20. The method of claim 15,
wherein the first and second substrate sub-layers are first and second glass sub-layers, and the substrate core layer is a glass core layer; and
wherein the method further includes:
forming at least one through glass via (TGV) in the glass core layer that extends through the first and second glass sub-layers, and
wherein the at least one TGV contacts at least one conductive trace of the first RDL.
